(19) United States
(12) Patent Application Publication
(10) Pub. No.: US 2015/0027532 A1
(43) Pub. Date: Jan. 29, 2015

(54) SOLAR CELL, SOLAR CELL MODULE AND METHOD OF MANUFACTURING SOLAR CELL

(71) Applicant: SANYO ELECTRIC CO., LTD., Osaka (JP)

(72) Inventors: Tsutomu YAMAGUCHI, Osaka (JP); Masayoshi ONO, Osaka (JP); Naoteru MATSUBARA, Osaka (JP); Tsuyoshi TAKAHAMA, Osaka (JP); Mitsuaki MORIGAMI, Osaka (JP)

(21) Appl. No.: 14/453,769

(22) Filed: Aug. 7, 2014

Related U.S. Application Data
(63) Continuation of application No. PCT/JP2012/081086, filed on Nov. 30, 2012.

(30) Foreign Application Priority Data
Dec. 2, 2011 (JP) 2011-264659
Feb. 16, 2012 (JP) 2012-031464

(51) Int. Cl. H01L 31/0236; H01L 31/0224; H01L 31/0203; H01L 31/18; H01L 31/0376; H01L 31/068

(52) U.S. Cl. CPC H01L 31/02366; H01L 31/03762; H01L 31/068; H01L 31/0203; H01L 31/1804; H01L 31/022441
USPC 136/256; 438/65

(57) ABSTRACT

A solar cell includes a photoelectric conversion body including one principal surface provided with a p-type surface and an n-type surface, a p-side electrode disposed on the p-type surface, an n-side electrode disposed on the n-type surface, and an insulating layer disposed between the p-side electrode and the n-side electrode and including a convex shaped surface.

### CROSS REFERENCE TO RELATED APPLICATIONS

This application is a continuation application of International Application No. PCT/JP2012/081086, filed on Nov. 30, 2012, entitled “SOLAR CELL, SOLAR CELL MODULE AND METHOD OF MANUFACTURING SOLAR CELL”, which claims priority from prior Japanese Patent Applications No. 2011-0264659 filed on Dec. 02, 2011 and No. 2012-031464 filed on Feb. 16, 2012, the entire contents of which are incorporated herein by reference.

### BACKGROUND OF THE INVENTION

1. Field of the Invention

This disclosure relates to a solar cell, a solar cell module and a method of manufacturing a solar cell.

2. Description of Related Art

Heretofore, a back contact solar cell has been known as a solar cell achieving improved photoelectric conversion efficiency (for example, see Patent Document 1).

Patent Document 1: Japanese Patent Application Publication No. 2005-101151

### SUMMARY OF THE INVENTION

In recent years, there has been a demand for further improvement in photoelectric conversion efficiency of back contact solar cells.

An embodiment of the invention has an objective to provide a solar cell with improved photoelectric conversion efficiency.

A first aspect of the invention is a solar cell including a photoelectric conversion body, a p-side electrode, an n-side electrode, and an insulating layer. The photoelectric conversion body includes a p-type surface and an n-type surface in one principal surface. The p-side electrode is disposed on the p-type surface. The n-side electrode is disposed on the n-type surface. The insulating layer is disposed between the p-side electrode and the n-side electrode. A surface of the insulating layer has a convex shape.

A second aspect of the invention is a solar cell module. The solar cell module includes the solar cell of the first aspect and a resin encapsulant. The resin encapsulant seals the solar cell. The insulating layer contains a resin.

A third aspect of the invention is a method of manufacturing a solar cell. The method of manufacturing a solar cell includes: preparing a photoelectric conversion body including one principal surface provided with a p-type surface and an n-type surface; forming an insulating layer on a border portion between the p-type surface and the n-type surface in the one principal surface of the photoelectric conversion body in such a way that an exposed portion of the p-type surface and an exposed portion of the n-type surface are defined by the insulating layer; and after forming the insulating layer, forming a p-side electrode on the p-type surface and an n-side electrode on the n-type surface concurrently by plating.

According to the first aspect of the invention, a solar cell with improved photoelectric conversion efficiency can be provided.

### BRIEF DESCRIPTION OF THE DRAWINGS

FIG. 1 is a schematic cross sectional diagram of a solar cell according to a first embodiment.

FIG. 2 is a schematic cross sectional diagram of a solar cell module according to the first embodiment.

FIG. 3 is a schematic cross sectional diagram of a solar cell according to a second embodiment.

FIG. 4 is a schematic cross sectional diagram of a solar cell according to a third embodiment.

FIG. 5 is an exemplary cross sectional diagram of multiple solar cells stacked in the third embodiment.

FIG. 6 is a schematic cross sectional diagram of a solar cell according to a fourth embodiment.

### DESCRIPTION OF EMBODIMENTS

Hereinafter, examples of preferred embodiments carrying out the invention are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated just schematically, and the dimensional ratio and the like of objects depicted in the drawings are different from those of the actual ones in some cases. The dimensional ratio and the like of objects are also different among the drawings in some cases. The specific dimensional ratio and the like of objects should be determined with the following description taken into consideration.

### First Embodiment

(Configuration of Solar Cell 1a)

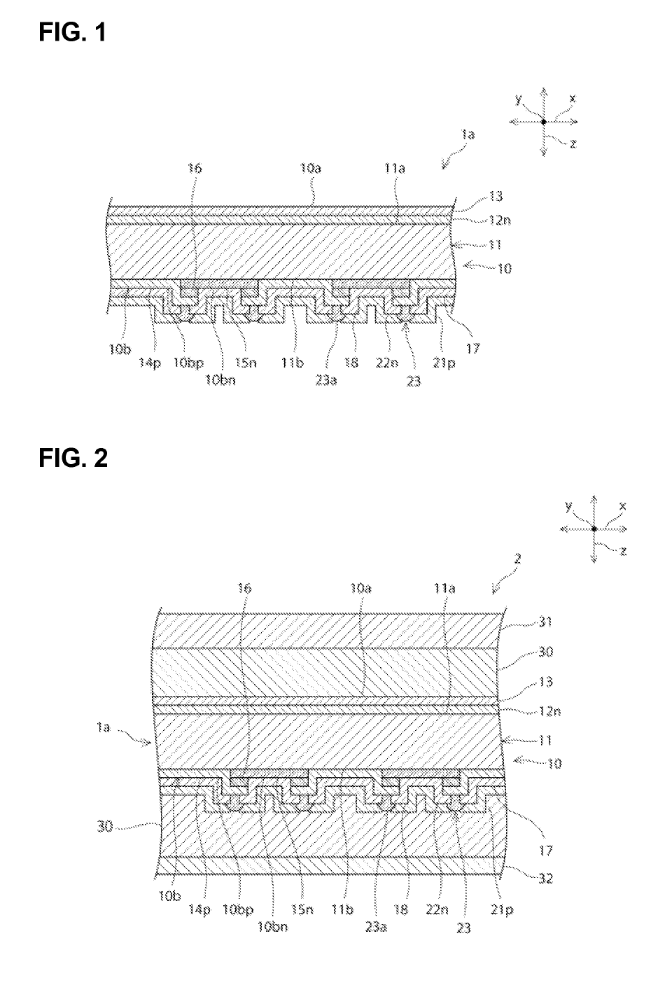

As illustrated in FIG. 1, solar cell 1a includes photoelectric conversion body 10 having light-receiving surface 10a and back surface 10b. Photoelectric conversion body 10 includes substrate 11. Substrate 11 is made of a semiconductor material. Substrate 11 may be made of a crystalline semiconductor such as crystalline silicon, for example, or the like. Substrate 11 has one conductivity type. Specifically, in the present embodiment, description is provided for an example where the conductivity type of substrate 11 is n-type.

Semiconductor layer 12n made of an n-type semiconductor which is of the same conductivity type as substrate 11 is disposed on first principal surface 11a located on a light-receiving surface 10a side of substrate 11. First principal surface 11a is substantially entirely covered with semiconductor layer 12n. Semiconductor layer 12n may be made of n-type amorphous silicon or the like. The thickness of semiconductor layer 12n may be about 1 nm to 10 nm, for example.

Here, a semiconductor layer made of a substantially-intrinsic i-type semiconductor may be provided between semiconductor layer 12n and first principal surface 11a. The semiconductor layer has a thickness of about several Å to 250 Å, for example, with which the semiconductor layer cannot substantially contribute to power generation.

Anti-reflective layer 13 is disposed on a surface of semiconductor layer 12n on the opposite side from substrate 11. Anti-reflective layer 13 has both a function to inhibit reflection and a function as a protective film. Anti-reflective layer 13 constitutes light-receiving surface 10a of photoelectric conversion body 10. Anti-reflective layer 13 may be made of, for example, silicon nitride or the like. Here, the thickness of anti-reflective layer 13 can be set as needed depending on a factor such as the wavelength of light whose reflection is to be inhibited. The thickness of anti-reflective layer 13 may be, for example, about 50 nm to 200 nm.

Semiconductor layer 14p made of a p-type semiconductor which is of a conductivity type different from substrate 11 is disposed on a portion of second principal surface 11b of substrate 11. Semiconductor layer 15n made of an n-type semiconductor which is of the same conductivity type as substrate 11 is disposed on at least part of the other portion of second principal surface 11b of substrate 11 where no semiconductor layer 14p is disposed. In this embodiment, second principal surface 11b is substantially entirely covered with semiconductor layer 14p and semiconductor layer 15n. Semiconductor layer 14p and semiconductor layer 15n maybe made of materials such as p-type amorphous silicon and n-type amorphous silicon, respectively.

Semiconductor layer 14p and semiconductor layer 15n constitute back surface 10b of photoelectric conversion body 10. Semiconductor layer 14p constitutes p-type surface 10bp, whereas semiconductor layer 15n constitutes n-type surface 10bn.

The thickness of semiconductor layer 14p may be about 2 nm to 20 nm, for example. The thickness of semiconductor layer 15n may be about 5 nm to 50 nm, for example. Here, a semiconductor layer made of a substantially-intrinsic i-type semiconductor may be provided between semiconductor layer 14p and second principal surface 11b. This semiconductor layer has a thickness of about several Å to 250 Å, for example, with which the semiconductor layer cannot substantially contribute to power generation. Similarly, a semiconductor layer made of a substantially-intrinsic i-type semiconductor may be provided between semiconductor layer 15n and second principal surface 11b. This semiconductor layer has a thickness of about several Å to 250 Å, for example, with which the semiconductor layer cannot substantially contribute to power generation. Such semiconductor layers made of substantially-intrinsic i-type semiconductors may be made of amorphous silicon or the like.

End portions of semiconductor layer 14p in an x axial direction overlap semiconductor layer 15n in a thickness direction z. Insulating layer 16 is disposed between the end portions of semiconductor layer 14p and semiconductor layer 15n. Insulating layer 16 maybe made of, for example, silicon nitride, silicon oxide or the like.

First seed layer 17 is disposed on semiconductor layer 14p. First seed layer 17 is a layer having a function as a seed to form p-side electrode 21p by plating as described later. On the other hand, second seed layer 18 is disposed on semiconductor layer 15n. Second seed layer 18 is a layer having a function as a seed to form n-side electrode 22n by plating as described later. First and second seed layers 17, 18 may be each made of transparent conductive oxide such as indium tin oxide (ITO) or at least one kind of metal such as Cu or Ag. Each of first and second seed layers 17, 18 may be formed of a multilayer including a transparent conductive oxide layer and a metal layer disposed on the transparent conductive oxide layer, for example. The thickness of each of first and second seed layers 17, 18 may be about 0.1 μm to 1.0 μm.

P-side electrode 21p to collect positive holes is disposed on first seed layer 17 disposed on p-type surface 10bp. P-side electrode 21p is electrically connected to p-type surface 10bp via first seed layer 17. On the other hand, n-side electrode 22n to collect electrons is disposed on second seed layer 18 disposed on n-type surface 10bn. N-side electrode 22n is electrically connected to n-type surface 10bn via second seed layer 18. Here, p-side electrode 21p may be disposed directly on p-type surface 10bp, while n-side electrode 22n may be disposed directly on n-type surface 10bn.

Each of p-side electrode 21p and n-side electrode 22n may preferably include a plating film, or may be more preferably formed of a plating film. For example, each of p-side electrode 21p and n-side electrode 22n may be formed of a laminate of two or more plating films. Specifically, each of p-side electrode 21p and n-side electrode 22n may be formed of a multilayer of a first plating film made of Cu and a second plating film made of Sn, for example.

The thickness of each of p-side electrode 21p and n-side electrode 22n may be about 20 μm to 30 μm.

Insulating layer 23 is disposed between p-side electrode 21p and n-side electrode 22n in a planar direction of back surface 10b of photoelectric conversion body 10. Surface 23a of insulating layer 23 has a convex shape. In other words, the cross-sectional shape of insulating layer 23 is a dome shape. Insulating layer 23 is provided between and on top of end portions of first seed layer 17 and second seed layer 18 which are neighboring in the x-axis direction. Insulating layer 23 is embedded between first seed layer 17 and p-side electrode 21p and between second seed layer 18 and n-side electrode 22n.

Insulating layer 23 may be made of an inorganic insulating material such as silicon oxide or silicon nitride, for example, but maybe preferably made of an organic insulating material such as an epoxy resin, an acrylic resin or a urethane resin, for example, and more preferably made of a plating resist made of a resist material containing an epoxy resin.

(Method of Manufacturing Solar Cell 1a)

Next, an example of a method of manufacturing a solar cell 1a is described.

Firstly, photoelectric conversion body 10 is prepared. Then, first seed layer 17 is formed on p-type surface 10bp and second seed layer 18 is formed on n-type surface 10bn. First and second seed layers 17, 18 may be formed by, for example, sputtering, a CVD (Chemical Vapor Deposition) technique, or the like.

Next, insulating layer 23 is formed. Specifically, insulating layer 23 having convex-shaped surface 23a is formed on each boundary portion between p-type surface 10bp and n-type surface 10bn of back surface 10b of photoelectric conversion body 10 in such a manner that an exposed portion of p-type surface 10bp and an exposed portion of n-type surface 10bn are defined by insulating layer 23. A method of forming insulating layer 23 is not particularly limited. For example, in the case where insulating layer 23 is made of an organic insulating material, insulating layer 23 may be formed by, for example, a screen printing method, an inkjet method, a photolithography method, or the like.

Subsequently, by plating such as electroplating, p-side electrode 21p is formed on p-type surface 10bp and n-side electrode 22n is formed on n-type surface 10bn, concurrently. Here, in order to keep p-side electrode 21p and n-side electrode 22n from being in contact with each other on insulating layer 23, it is preferable to form insulating layer 23 by using a plating resist.

As has been described above, in solar cell 1a, insulating layer 23 disposed between p-side electrode 21p and n-side electrode 22n has convex-shaped surface 23a. This makes it possible to secure a long distance on back surface 10b between p-side electrode 21p and n-side electrode 22n. Thus, even if the distance in the x-axis direction between p-side electrode 21p and n-side electrode 22n is set short, high insulating resistance between p-side electrode 21p and n-side electrode 22n can be achieved. This enables achievement of improved photoelectric conversion efficiency.

In addition, if no insulating layer 23 is provided and then a p-side electrode and an n-side electrode are formed by plating, the electrodes is formed over an area wider than the seed layers, and the p-side and n-side electrodes may come into contact with each other in some cases. To prevent contact between the p-side electrode and the n-side electrode, a large distance needs to be secured between the first seed layer and the second seed layer.

In contrast, since the present embodiment has insulating layer 23 provided, the distance between first seed layer 17 and second seed layer 18 can be made short because p-side electrode 21p and n-side electrode 22n are kept from contacting each other. The convex shape of surface 23a of insulating layer 23 more effectively keeps p-side electrode 21p and n-side electrode 22n from contacting each other, and enables a much shorter distance between first seed layer 17 and second seed layer 18. Accordingly, more improved photoelectric conversion efficiency can be achieved.

Moreover, the formation of insulating layer 23 by using a plating resist more effectively keeps p-side electrode 21p and n-side electrode 22n from contacting each other, and enables a much shorter distance between first seed layer 17 and second seed layer 18. Accordingly, more improved photoelectric conversion efficiency can be achieved.

Insulating layer 23 is provided between and on first seed layer 17 and second seed layer 18. Here, a width of insulating layer 23 on the surface plane of first seed layer 17 and second seed layer 18 is longer than a width insulating layer 23 on the surface plane of semiconductor layer 14p and semiconductor layer 15n. For this reason, insulating layer 23 can inhibit first and second seed layers 17, 18 from peeling off from photoelectric conversion body 10.

### (Solar Cell Module 2)

FIG. 2 is a schematic cross-sectional diagram of a solar cell module in the first embodiment. As illustrated in FIG. 2, solar cell module 2 includes solar cell 1a. Solar cell la is sealed by resin encapsulant 30. Light-receiving surface member 31 is provided on a light-receiving surface 10a side of resin encapsulant 30. On the other hand, back surface member 32 is provided on a back surface 10b side of resin encapsulant 30.

When insulating layer 23 contains a resin, the adherence between insulating layer 23 and resin encapsulant 30 is high. For this reason, resin encapsulant 30 can more suitably seal solar cell 1a, and can inhibit moisture or the like from reaching solar cell 1a.

To be more specific, in the case where a resist material containing an epoxy material in an amount of 30% is used for insulating layer 23 and an ethylene-vinyl acetate copolymer (EVA) is used for resin encapsulant 30, the adhesive strength between insulating layer 23 and resin encapsulant 30 is 75 N, and the adhesive strength between semiconductor layer 14p and insulating layer 23 is 75 N or higher. On the other hand, if a solar cell has no insulating layer 23, solar cell module 2 is configured such that semiconductor layer 14p and resin encapsulant 30 adhere to each other. In this case, the adhesive strength between semiconductor layer 14p and resin encapsulant 30 is 42 N. Based on the above results, it is found that the provision of insulating layer 23 leads to an increase in the adhesive strength between semiconductor layer 14p and resin encapsulant 30, and therefore makes it possible to inhibit entry of moisture or the like. Incidentally, the adhesive strengths presented above were each measured by a test of tensile strength between the two kinds of layers.

Note that resin encapsulant 30 may be made of a resin such for example as ethylene-vinyl acetate copolymer (EVA), polyvinyl butyral (PVB), polyethylene (PE), or polyurethane (PU). Light-receiving surface member 31 may be formed of, for example, a translucent or transparent glass plate, plastic plate or the like. Back surface member 32 may be formed of, for example, a resin film such as a polyethylene terephthalate (PET) film, a multilayer film in which a metal foil such as an Al foil is inserted between stacked resin films, a steel sheet, or the like.

Hereinafter, other preferable embodiments of the invention are described. In the following description, components having substantially the same functions as those in the foregoing first embodiment are referred to with the same reference numerals, and the explanation thereof is omitted.

### Second Embodiment

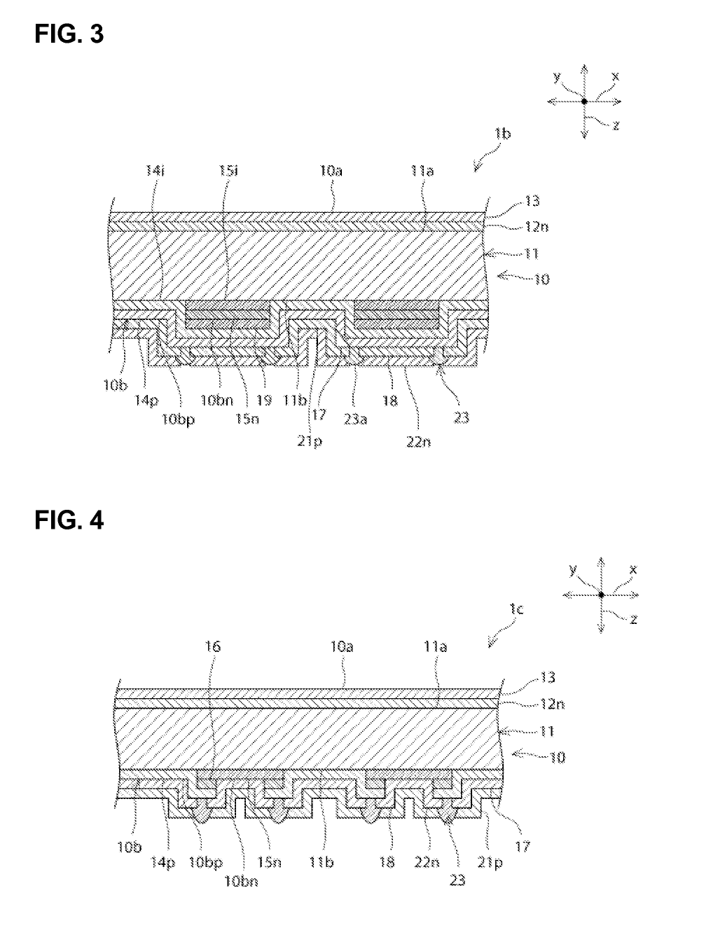

FIG. 3 is a schematic cross sectional diagram of solar cell 1b in a second embodiment. As illustrated in FIG. 3, solar cell 1b in the second embodiment is different from solar cell 1a in the first embodiment in term of the configuration of photoelectric conversion body 10. The configuration of photoelectric conversion body 10 in the present embodiment is described below.

Semiconductor layer 14i made of a substantially-intrinsic i-type semiconductor is provided between substrate 11 and semiconductor layer 14p. Semiconductor layer 14i has a thickness of about several Å to 250 Å, for example, with which semiconductor layer 14i cannot substantially contribute to power generation. Semiconductor layer 15i made of a substantially-intrinsic i-type semiconductor is provided between substrate 11 and semiconductor layer 15n. Semiconductor layer 15i has a thickness of about several Å to 250 Å, for example, with which semiconductor layer 15i cannot substantially contribute to power generation.

Semiconductor layer 14i and semiconductor layer 14p are provided so as to substantially entirely cover second principal surface 11b including a portion above semiconductor layer 15n. Thus, Semiconductor layer 14i and semiconductor layer 14p are also provided above semiconductor layer 15n. Recombination layer 19 is provided between semiconductor layer 15n and semiconductor layer 14p. In this way, another semiconductor layer maybe further provided on n-type surface 10bn constituted by semiconductor layer 15n.

Electric charges collected on p-type surface 10bp are extracted from p-side electrode 21p in direct contact with semiconductor layer 14p as in the case of the first embodiment. On the other hand, electrons collected on n-type surface 10bn are extracted from n-side electrode 22n via recombination layer 19, semiconductor layer 14i, and semiconductor layer 14p

Recombination layer 19 may be made of a material such as a semiconductor material in which many midgap levels exist in energy bands, or a metallic material capable of coming in ohmic contact with a p-type semiconductor layer. The selection of such a material makes it possible to reduce a loss of electrons extracted from n-side electrode 22n. More specifically, recombination layer 19 may be made of, for example, p-type or n-type amorphous silicon, p-type or n-type microcrystalline silicon, or the like.

P-type surface 10bp and n-type surface 10bn are connected with semiconductor layer 14i and semiconductor layer 14p interposed in between. However, semiconductor layer 14i and semiconductor layer 14p have such small film thicknesses as to have high resistance that allows only a small current to flow. This configuration enables generated electric current to be efficiently extracted from p-side electrode 21p and n-side electrode 22n without needing the processes of forming semiconductor layer 14i and semiconductor layer 14p. Also, solar cell 1b can produce the same effects as solar cell 1a. Moreover, solar cell 1b does not need a patterning process of semiconductor layer 14p and the like. Accordingly, the manufacturing cost can be reduced.

### Third Embodiment

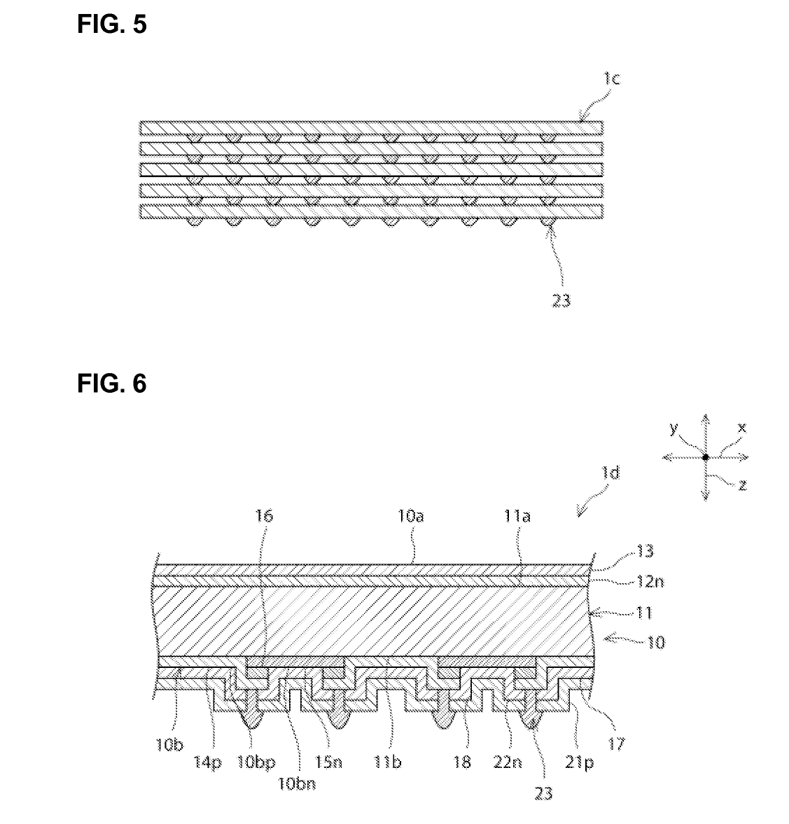

FIG. 4 is a schematic cross sectional diagram of solar cell 1c according to a third embodiment. As illustrated in FIG. 4, solar cell 1c includes insulating layer 23 protruding from p-side electrode 21p and n-side electrode 22n. Insulating layer 23 is made of an elastic body such as a resin. For this reason, if multiple solar cells 1c are stacked as illustrated in FIG. 5, only insulating layers 23 made of the elastic bodies contact neighboring solar cells 1c. The parts of solar cells 1c other than insulating layers 23 are kept from contacting neighboring solar cells 1c. This inhibits solar cells 1c from being damaged even if solar cells 1c are stacked without resin sheets or the like inserted therebetween. As a result, solar cells 1c are easy to store, which enables reduction in the manufacturing costs for solar cell module 2 as well.

Incidentally, all insulating layers 23 do not necessarily have to protrude from p-side electrode 21p and n-side electrode 22n, but only some of insulating layers 23 may protrude from p-side electrode 21p and n-side electrode 22n.

### Fourth Embodiment

FIG. 6 is a schematic cross sectional diagram of solar cell 1d according to a fourth embodiment. In solar cell 1c, insulating layer 23 is formed before the formation of p-side electrode 21p and n-side electrode 22n. In contrast, in solar cell 1d, insulating layer 23 is formed after the formation of p-side electrode 21p and n-side electrode 22n. Even in this case, the same effects as those described in the third embodiment can be obtained.

1. A solar cell, comprising:
a photoelectric conversion body including one principal surface provided with a p-type surface and an n-type surface;
a p-side electrode disposed on the p-type surface;
an n-side electrode disposed on the n-type surface; and
an insulating layer disposed between the p-side electrode and the n-side electrode, and including a surface formed in a convex shape.

2. The solar cell according to claim 1, wherein the p-side electrode and the n-side electrode each include a plating film.

3. The solar cell according to claim 2, further comprising:
a first seed layer disposed between the p-type surface and the p-side electrode; and
a second seed layer disposed between the n-type surface and the n-side electrode, wherein
the insulating layer is provided between and on top of neighboring end portions of the first seed layer and the second seed layer.

4. The solar cell according to claim 1, wherein
the photoelectric conversion body includes:
a substrate made of a semiconductor material;
a p-type amorphous silicon layer disposed on one principal surface of the substrate and forming the p-type surface; and
an n-type amorphous silicon layer disposed on the one principal surface of the substrate and forming the n-type surface.

5. The solar cell according to claim 1, wherein
the insulating layer is formed of an elastic body, and
the insulating layer protrudes from the p-side electrode and the n-side electrode.

6. A solar cell module comprising:
the solar cell according to claim 1; and
a resin encapsulant that seals the solar cell, wherein
the insulating layer contains a resin.

7. A method of manufacturing a solar cell, comprising:
preparing a photoelectric conversion body including one principal surface provided with a p-type surface and an n-type surface;
forming an insulating layer on a border portion between the p-type surface and the n-type surface in the one principal surface of the photoelectric conversion body in such a way that an exposed portion of the p-type surface and an exposed portion of the n-type surface are defined by the insulating layer; and
after forming the insulating layer, forming a p-side electrode on the p-type surface and an n-side electrode on the n-type surface by plating.

8. The method of manufacturing a solar cell according to claim 7, wherein in the forming of an insulating layer, a surface of the insulating layer is formed into a convex shape.

9. The method of manufacturing a solar cell according to claim 7, wherein in the forming of an insulating layer, the insulating layer is formed of a resist material containing an epoxy resin.

10. The method of manufacturing a solar cell according to claim 7, further comprising forming a first seed layer on the p-type surface and a second seed layer on the n-type surface concurrently, wherein
the insulating layer is formed between and on top of neighboring end portions of the first seed layer and the second seed layer.
